(19) United States
(12) Patent Application Publication
(10) Pub. No.: US 2010/0206354 A1
(43) Pub. Date: Aug. 19, 2010

(54) Portable Power System

(76) Inventors: James Irvine Greene, JR., Pulaski, TN (US); Wilson Pershing Stevenson, III, Seattle, WA (US)

Correspondence Address: DOUGLAS T. JOHNSON;MILLER & MARTIN, 1000 VOLUNTEER BUILDING, 832 GEORGIA AVENUE, CHATTANOOGA, TN, 37402-2289, US

(21) Appl. No.: 12/705,778

(22) Filed: Feb. 15, 2010

Related U.S. Application Data
(60) Provisional application No. 61/152,853, filed on Feb. 16, 2009.

(51) Int. Cl. H01L 31/045

(52) U.S. Cl. 136/245

(57) ABSTRACT

A mobile power system provides a housing, such as a container having at least one door at a first end. From the first end a first set of arrays can extend from a stowed configuration inside of the housing to an extended configuration through the first end. Slides and rollers can facilitate this transition. Once in the extended configuration, the first set of arrays can then transition to a deployed configuration such as by rotating at least one auxiliary array relative to a main array. A control panel, preferably accessible from outside of the housing, can automatedly transition the first set of arrays from the stowed to at least the extended, if not deployed configuration. A similarly operating set of second arrays can be utilized with some embodiments.

### CLAIM OF PRIORITY

This application claims the benefit of U.S. Provisional Patent Application No. 61/152,853 filed Feb. 16, 2009.

### FIELD OF THE INVENTION

The present invention relates to a power system and more particularly to mobile, self-contained power systems which are preferably user friendly in terms of deployment and shipping.

### BACKGROUND OF THE INVENTION

U.S. Pat. No. 7,230,819 shows an interesting mobile power system which utilizes a full sized shipping container to house a number of solar panels and a wind turbine. The solar panels are connected to the exterior of the shipping container with removable strut assemblies 20 connected to brackets 14 which are described as being mounted onto the housing which is a shipping container. The brackets, strut assemblies and arrays are intended to be removed and stored in the housing during transport. The wind turbine can also be selectively connected to a corner of the shipping container.

As stated by the owner of the '819 Patent: “the brackets 14 are removably coupled to the housing, for example, bolt connections extend through the brackets 14 and into an appropriately located passages 39 in the housing 12.” This will necessarily require the operator to first remove the brackets from the shipping container and install them on shipping container. Next, the strut assemblies will be installed and adjust them appropriately with the arrays connected thereto. Meanwhile, while personnel are connecting the panels 18, opportunities would appear to arise to possibly drop or otherwise damage solar panel by failing to properly follow the installation instructions to provide the embodiment as shown in FIG. 1. Taking the structure apart and re-storing the equipment would appear to involve similar risks.

Accordingly, an improved method of deploying and re-storing solar panels relative to a housing is believed to be necessary for a mobile power system to be easily deployed and stowed in the field.

### SUMMARY OF THE INVENTION

It is an object of the present invention to provide a mobile power system which includes a container or other housing into which power generating devices such as a solar arrays can be more rapidly deployed from and stowed in than prior art alternatives.

It is another object of the present invention to provide improved mobile power systems.

It is another object of at least some embodiments of the present invention to provide an improved mobile power system in which at least one power generating system is slidably received into the container and slidably extends therefrom preferably while maintaining proper electrical connections internal to the housing for use.

It is another object of at least some embodiments of the present invention to provide a solar array system supported by rollers on which the solar arrays can be extended into and out from the container preferably while still connected to the container by at least one of an electrical connection and/or tray.

It is another object of at least some embodiments of the present invention to provide a housing containing a battery and a DC to AC inverter.

It is another object of at least some embodiments of the present invention to provide a mobile power system with a housing having an improved retracted and deployed configuration.

It is another object of at least some embodiments of the present invention to provide an improved mobile power system in which at least some solar arrays are supported by trays which are slidably received into and extended from a housing to a deployed configuration.

It is still a further object of still some embodiments of the present invention to provide a mobile power system in which solar arrays may be slidably extended from a container and then at least some arrays pivoted or otherwise moved while remaining connected to the extended solar array to a preferable position.

Accordingly, in accordance with the presently preferred embodiment of the present invention, a mobile power system is provided in the form of a modified shipping container. More preferably, at least for some embodiments, a modified half-height shipping container may be utilized. The container may be armored in some embodiments to resist penetration by projectiles. Furthermore, within the housing are preferably stored at least one, if not two, sets of solar panel arrays which are slidingly received within the housing in a storage configuration, such as with the respective doors shut.

In order to transition to a deployed configuration, the doors on at least one side, if not both sides, are opened and then at least one set of solar arrays are extended from within the housing, preferably while maintaining an electrical connection with at least one of a battery, a control center and/or a DC to AC inverter. With a first solar panel set positioned in an extended configuration, it is preferable that each set of panels include at least one pivoting or otherwise suitably connected solar panel array which can then be positioned relative to the initially extended first array in an effort to catch more sunlight. In the presently preferred embodiment, unfolding at least one top panel, if not two panels from an initial position is possible. When in the storage configuration various array groups in the set are stacked (not necessarily in contact with one another) to possibly effectively substantially triple the area when fully deployed.

In the presently preferred embodiment of the present invention, few, if any, special tools are required in the field. In fact, no tools at all are preferably required to transition from the storage to the extended to the deployed configurations and back. At least in some embodiments of the present invention, at least two sets of solar panel arrays are stored within the container in the storage configuration. Both sets are preferably slidable out of opposing ends to the extended configuration. Both sets also may have at least some arrays which are pivotable relative to others to provide a deployed configuration. In a preferred embodiment, the arrays in a storage configuration are effectively arranged on top of one another with a control panel and battery contained and retained within the container.

A full sized container or other housing could be utilized to house a wind turbine or provide other capabilities in the housing as well. The housing could have uses taught in U.S. Pat. No. 7,230,819 which is incorporated by reference herein as well or other uses.

### BRIEF DESCRIPTION OF THE DRAWINGS

The particular features and advantages of the invention as well as other objects will become apparent from the following description taken in connection with the accompanying drawings in which:

FIG. 1 is a top perspective view of a mobile power system in a stowed configuration in accordance with a presently preferred embodiment of the present invention;

FIG. 2 is the power system of FIG. 1 with doors on both ends open in preparation for extending the solar arrays contained therefrom;

FIG. 3 shows an end view of the power system shown in FIGS. 1 and 2 with the doors open as shown in FIG. 2;

FIG. 4 shows the mobile power system of FIG. 1-3 in an extended and deployed configuration with the solar panel arrays directed in an intended direction; and

FIG. 5 is a cross section of a presently preferred housing wall shown in FIG. 1.

### DETAILED DESCRIPTION OF THE DRAWINGS

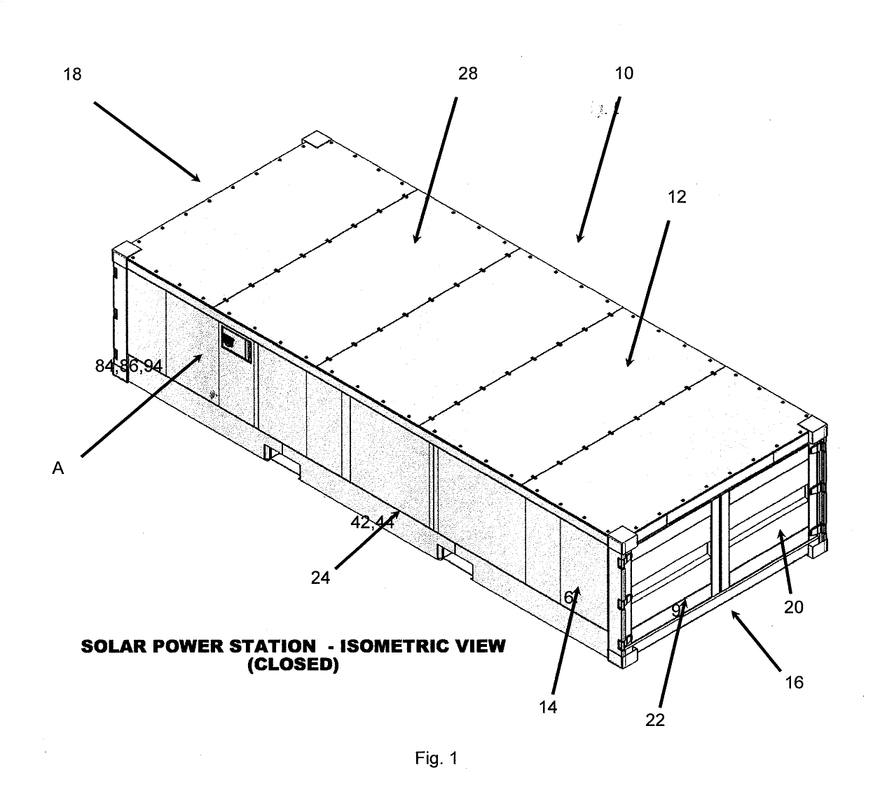

FIG. 1 shows a presently preferred embodiment of the present invention in the form of a mobile power system 10. Mobile power system 10 is preferably comprised of housing 12 which is illustrated as a modified shipping container and more preferably as a modified half-height shipping container that has been armor plated with plating 14. Armor plating 14 has been known to reduce the possibility of penetration by projectiles such as could be fired from shoulder-fired or other weapons of an adversary, particularly in hostile environments.

At opposing ends, or at least one of the ends of container 18, a pair of doors 20,22 are preferably provided and are shown in a shut configuration thereby retaining the contents of the housing 12 therein for a stowed or shipping condition. While doors 20,22 are illustrated, other closure systems as are known in the art may be utilized with the other housing embodiments. Furthermore, while the ends 16,18 are preferred located for interior access, egress and ingress, sides 26, as well as top 28 and possibly bottom (not illustrated) could be utilized for accessing, ingressing and egressing the interior of the container in other embodiments.

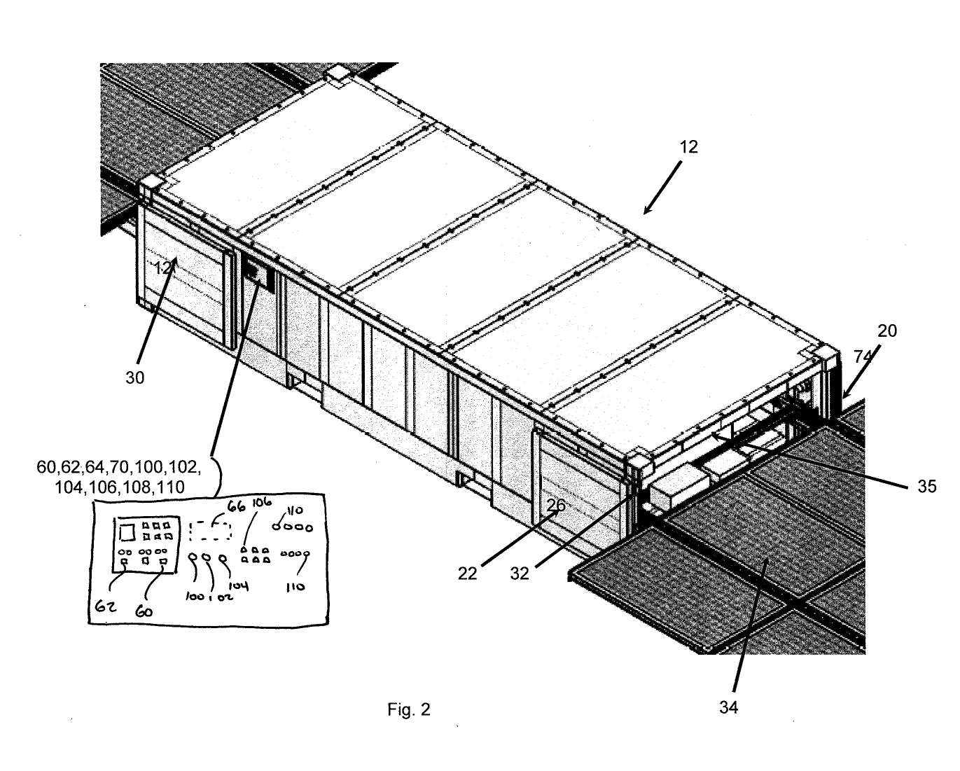

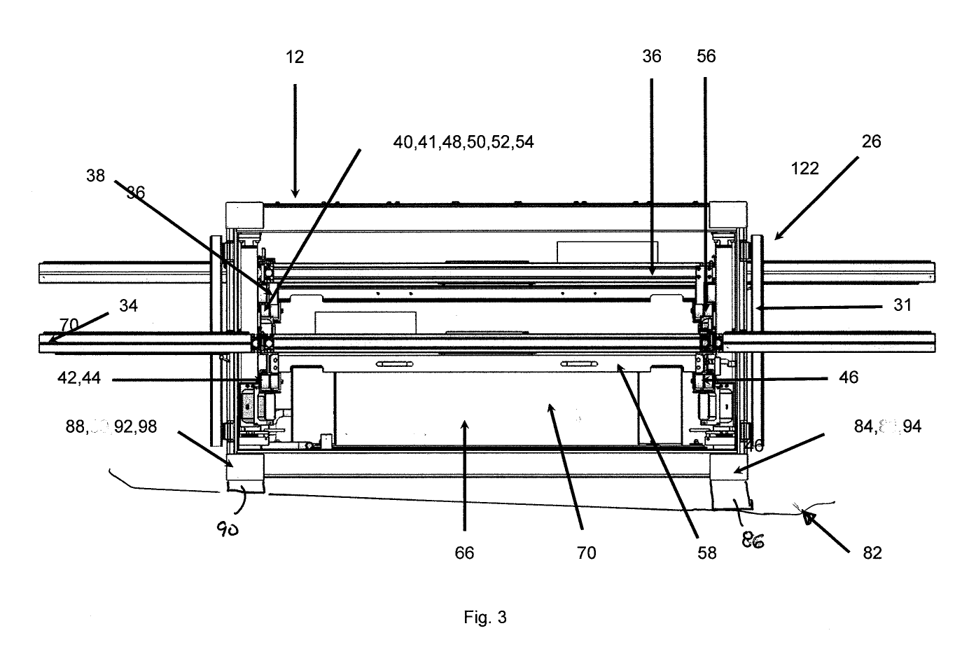

FIGS. 2 and 3 show the doors 20,22 as well as door 30 if utilized in a fully open position. The doors are rotated about hinges 32 in the preferred embodiment. Other methods of opening the doors may be employed. Furthermore, doors may not necessarily be opened to a fully opened position with the doors 20,22,30 parallel with the respective sides 24,26 in all embodiments. Doors 20,22,30,31 are at least open sufficiently enough to allow egress of a first set of arrays 34 from within interior 36 of housing 12. The first set of arrays 34 as well as a preferred second set of arrays 36 are shown in FIG. 3. Sets 34,36, are preferably fully contained within interior 35 in the stowed configuration shown with reference to FIG. 1.

With the respective doors 20,22,30,31 open as is shown in FIGS. 2 and 3, the first and second solar arrays 34,36 can be slidably deployed, rollingly moved, extended or otherwise extended from an interior 35 of housing 12. Slides 38 may rest upon rollers 42,44,46. Furthermore, rollers 40 may also be useful to provide support for array 36 and/or top support for slides 38 when it is extended relative to the interior 35 of the housing 12. In fact, in the embodiment illustrated when the first set of arrays 34 is extended, the motion of rollers 40,48,50,52,54,56 and possibly others may assist in simultaneously extending second solar array set 36. In other embodiments, separate sets of rollers may cooperate with the respective sets of arrays 34,36 and movement of the sets 34,36 need not be tied together mechanically in all embodiments.

The rollers illustrated, namely rollers 40,48,50,52,54,56 are representative rollers in that fewer or more can be utilized in other embodiments. Furthermore, the rollers 40,42,50,52,54,56 may be coupled directly to the slides 38. First set 32 has an end plate connected thereto which may assist in supporting the slide 38 or opposing slides for each of the perspective arrays 34,36.

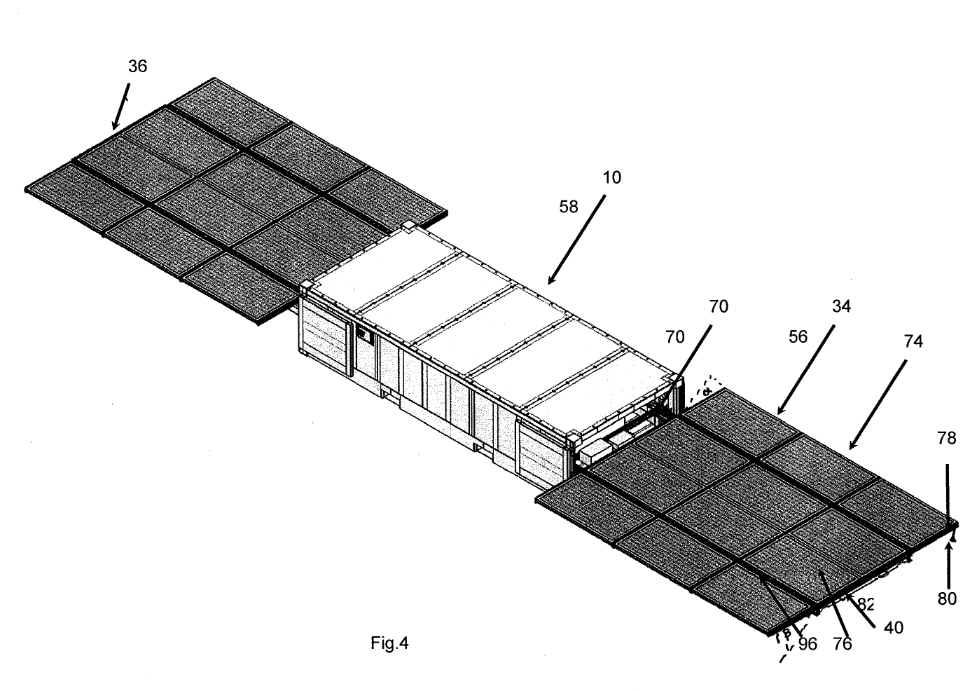

As can be seen from the storage configuration and the deployed configuration shown in FIG. 4 transition through the extended position easy proposition for the applicant's design. Specifically, control panel 60 may have a button such as button or other operator 62 activated whereby perhaps after a delay, the array sets 34,36 begin to proceed toward the extended configuration and then possibly on to the deployed configuration in an automated manner, possibly semi-automated manner, assisted and/or manually operated. Control panel 60 may be deployed toward the one end such as end 16 interior to the interior 35 of a housing, on a side, or elsewhere. Alternatively, control panel 60 may extend through a portion of the various walls of the housing 12 such as the doors 20,22,30,31, sides 24,26, top 28 or bottom. Operator 62 may be in other locations for other embodiments or still further embodiments may be manually extended and/or deployed.

Connection locations 64 may be similarly or dissimilarly provided in various embodiments as will be explained in further detail below. Inverter 66 is illustrated in phantom for converting AC to DC and/or DC to AC current at the desired voltage levels. While the deployment of the arrays 34,36 could be automated, it is also further possible that they could be manually pulled out, preferably while remaining connected such as shown by connector 70 to the electrical communication with control panel 60 as well as inverter 66 and/or battery 70. As the arrays 34,36 are deployed, they are transported and/or assisted by the various rollers 40-56 and/or others. Rollers 41,42,44 as well as cooperating rollers 46,56 and others not shown can assist in holding the first array 34 in a cantilevered and extended position such as is shown in FIG. 4. Downwardly extending support (not shown) may be provided towards the end plate 34 or other portion along the array set 34.

With the array set 34 in the extended position, at least one auxiliary array 72 and/or 74 may be moved such as by rotating relative to main array 76. Stand 78 is useful and in many embodiments assist in securing the second auxiliary array 74 in position if not resting on the ground as illustrated for that of first array 70 when at angle β. Furthermore, the stand 78 may be a different height so that the angular position of auxiliary array 72,74 relative to main array 76 can be selected by the user such as at angle(s) α. Furthermore, the control panel 60 may be able to account for the position the sun based on sensors such as sensor 80 to provide the panels of various arrays 72,74 at desired angular relationships relative to the sun particularly if the hinges are automatedly moved to desired angular positions. Furthermore, it may be that the main array 76 is also angularly positionable relative to a ground surface 82 such as with extendable feet 84,86,88,90 as shown in FIG. 3 which can be received in pump/housings 92,94 which may direct the respective feet 86-90 from the interior 36 or at least flush with the bottom to a desired angular location. Other angular positioning means may be employed in other embodiments.

The deployment of first and second auxiliary arrays 72,74 relative to the main array 76 can be automated, assisted, or manually performed whereby the auxiliary arrays 72,74 are rotated about hinges such as hinge 96 with the aid of pneumatic, hydraulic or other mechanism which could be facilitated by hydraulic pump 98 illustrated in FIG. 3. Storage could be similarly automated, assisted, and/or manually performed in various embodiments from various stages of deployment. Alternatively, if there are no automated extension steps to provide the extended and/or deployed configurations as shown in FIG. 4, the operator could grasp the array 34 such as at the end plate 78, pull it outwardly and then rotate the auxiliary arrays 72,74 relative to the main array 76 about the hinges such as 96. While hinges are shown as the presently preferred method for articulating or otherwise moving the auxiliary 72,74 relative to the main array 76, other connection systems could be employed which may also not necessarily require the use of specialty, if any, tools by an operator in order to position the arrays 72-76 in desired configurations. Also, auxiliary arrays 72, 74 may be moved to angles α and/or β at preselected and/or a user selected positions. Furthermore, the control panel 60 or other mechanisms can be utilized to assist in providing the feet 84-90, if provided, at a desired configuration. Feet 84-90 or other positioning device could be controlled by a control panel 60 possibly in connection with sensor 80 to adjust angular orientation of at least some arrays 72,74,76.

One advantage of at least some embodiments of this design over the prior art at least for some embodiments is the ability for the connector 70 to remain connected from the storage to the displayed configuration whereby users would need only place the system 10 in a deployed configuration as is shown in FIG. 4 and then plug in electrical devices and outlets such as outlets 100-104 which could be 440 V outlets or other voltage outlets, 120 V outlets such as outlets 106, 240 V outlets such as 108 and/or others. Furthermore, input such as inputs 110 could receive input from other sources such as other solar arrays, generators of various kinds including diesel, wind or other sources. Other inputs and supporting devices could be deployed/stored in a similar or dissimilar manner as array sets 34,36 or separately stored.

In the presently preferred embodiment, interior 36 is not sufficiently large enough to house a wind turbine or personnel compartment therein. However, it may be that future embodiments could have that capability such as by providing a sufficient amount of space in the interior 36 which is not utilized by the arrays 34,36, the control panel 60 or battery 70 or other associated equipment. In fact, it may be possible to make the extension of a wind turbine fit within container 12 and be deployable to a deployable configuration in a somewhat similar manner as shown for the array set 34,36 except that when the pole is deployed laterally or emerges from the container or housing 12, it could then be lifted. A wenched cable or other mechanism could be employed. Still other embodiments may have other methods for raising a turbine support in other embodiments.

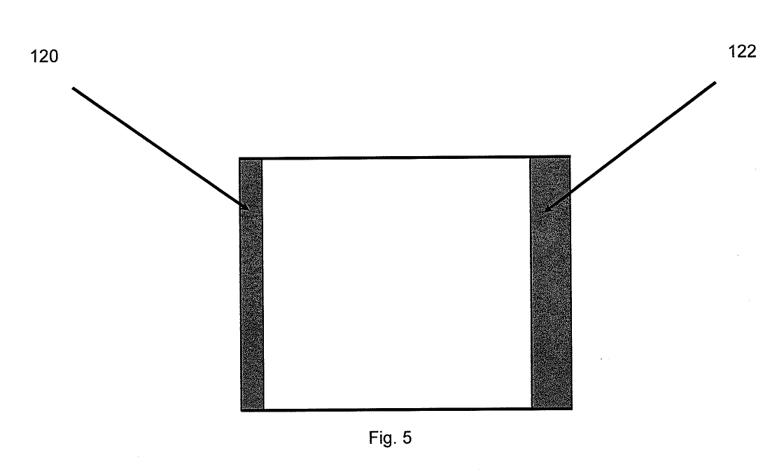

FIG. 5 shows a presently preferred cross section of armor plating with a 3 mm plate 120 spaced a distance from an 8 mm body portion 122. A projectile may the first surface 120 and possibly tumble so that it can be caught or otherwise not penetrate the second surface 122. Other armor plating techniques could be utilized in other embodiments, if at all.

Numerous alterations of the structure herein disclosed will suggest themselves to those skilled in the art. However, it is to be understood that the present disclosure relates to the preferred embodiment of the invention which is for purposes of illustration only and not to be construed as a limitation of the invention. All such modifications which do not depart from the spirit of the invention are intended to be included within the scope of the appended claims.

Having thus set forth the nature of the invention, what is claimed herein is:

1. A mobile power station comprising:
a housing having at least one door at a first end, said door having a closed configuration and a first configuration displaced from the closed configuration;
a first set of solar arrays supported by slides, said first set of arrays completely contained within the container in a stowed configuration, and extendable from the stowed configuration to an extended configuration through the first end with the slides remaining operably coupled to the first set of arrays and the housing as the first set of solar arrays extends from the stowed to the extended configuration; and wherein said first set of solar arrays has a deployed configuration wherein at least some of the first set of solar arrays receive sunlight externally from the container and generate electricity.

2. The mobile power station of claim 1 wherein the first end has a pair of doors hingedly connected to sides of the housing, and rotation of the doors transitions the housing from shut to open.

3. The mobile power station of claim 1 further comprising rollers connected to the first set of solar arrays, said rollers cooperating with the slides facilitating the extension of the first set of solar arrays to the extended configuration.

4. The mobile power station of claim 3 further comprising nesting slides facilitating the transition from the stowed configuration to the extended configuration with the first set of arrays completely external to the housing in the extended configuration.

5. The mobile power station of claim 1 further comprising a control panel accessible through one of the first end and through the housing.

6. The mobile power station of claim 1 wherein the control panel has a setting that when activated deploys the first set of arrays from the stowed configuration to at least the extended configuration.

7. The mobile power station of claim 6 wherein the control panel has a setting that when activated, deploys the first set of arrays from the stowed configuration to the deployed configuration

8. The mobile power station of claim 6 wherein the control panel has a setting that when activated transitions the first set of arrays from the extended configuration back to the stowed configuration.

9. The mobile power station of claim 1 wherein the slides cantileveredly extend the first set of arrays from the housing in at least one of the deployed and extended configurations

10. The mobile power station of claim 1 further comprising a second set of arrays, said second set of arrays supported by slides, said second set of arrays completely contained within the container in a stowed configuration, and extendable from the stowed configuration to an extended configuration through a second end, opposite the first end, with the slides remaining operably coupled to the second set of arrays and the container as the second set of solar arrays extends from the stowed to the extended configuration; and
a deployed configuration wherein at least some of the second set of solar arrays receive sunlight externally from the container and generate electricity.

11. The mobile power station of claim 10 further comprising a control panel, said control panel having a setting that when activated, the second set of solar arrays extend from the stowed to the extended configuration.

12. The mobile power station of claim 1 wherein the housing has extendable feet at least one of the first end, and a second end opposite the first end, said extendable feet providing elevational adjustment of at least one of the first and second ends.

13. The mobile power station of claim 1 wherein the first set of arrays further comprises at least a main array and a first auxiliary array, said first auxiliary array operably coupled to the main array, wherein when in the extended configuration, the first auxiliary array is closer to the main array than in the deployed configuration whereby the first auxiliary array is rotated relative to the main array away from the main array.

14. The mobile power station of claim 1 wherein the housing is armor plated.

15. A mobile power station comprising:
a housing having at least one door at a first end, said door having a closed configuration and a first configuration displaced from the closed configuration;
a first set of solar arrays completely contained within the container in a stowed configuration and extendable from the stowed configuration to an extended configuration through the first end with the first set of solar arrays remaining operably coupled to the housing as the first set of solar arrays extends from the stowed to the extended configuration; and wherein said first set of solar arrays has a deployed configuration wherein at least some of the first set of solar arrays receive sunlight externally from the container and generate electricity; and
a control panel having a setting that when activated at least assists in deploying the first set of arrays from the stowed configuration to at least the extended configuration.

16. The mobile power station of claim 15 wherein the control panel is accessible externally from the housing.

17. The mobile power station of claim 15 further comprising a second set of solar arrays completely contained within the container in a stowed configuration and extendable from the stowed configuration to an extended configuration through a second end, opposite the first end, with the second set of solar arrays remaining operably coupled to the housing as the second set of solar arrays extends from the stowed to the extended configuration; and wherein said second set of solar arrays has a deployed configuration wherein at least some of the second set of solar arrays receive sunlight externally from the container and generate electricity.

18. The mobile power station of claim 17 wherein the first and second sets of solar arrays are supported by slides with the first set of solar arrays stored above the second set of solar arrays in the stowed configurations.

19. The mobile power station of claim 18 wherein the first and second sets of solar arrays are connected to rollers, said rollers cooperating with the slides to facilitate the transition from the stowed configuration to at least the extended configuration.

20. The mobile power station of claim 18 wherein the first and second sets of solar arrays linearly extend from the first and second ends of the housing respectively when transitioning from the stowed to the extended configurations.
